(19) United States
(12) Patent Application Publication
(10) Pub. No.: US 2025/0191906 A1
(43) Pub. Date: Jun. 12, 2025

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: KOKUSAI ELECTRIC CORPORATION, Tokyo (JP)

(72) Inventors: Yusuke TERUI, Toyama-shi (JP); Yoshitomo HASHIMOTO, Toyama-shi (JP); Tatsuru MATSUOKA, Toyama-shi (JP); Tomoya NAGAHASHI, Toyama-shi (JP)

(73) Assignee: KOKUSAI ELECTRIC CORPORATION, Tokyo (JP)

(21) Appl. No.: 19/053,555

(22) Filed: Feb. 14, 2025

Related U.S. Application Data
(63) Continuation of application No. PCT/JP2022/031442, filed on Aug. 19, 2022.

(51) Int. Cl. H01L 21/02; C23C 16/30; C23C 16/455; C23C 16/52

(52) U.S. Cl. CPC H01L 21/02131; C23C 16/30; C23C 16/45523; C23C 16/52; H01L 21/02208

(57) ABSTRACT

There is provided a technique that includes: forming a film containing a first element, a second element, carbon, and a halogen on a substrate by performing a cycle a predetermined number of times, the cycle including: (a) supplying a source containing the first element, carbon, and the halogen and not containing a chemical bond between carbon and hydrogen to the substrate; and (b) supplying a reactant containing the second element different from the first element to the substrate.

### CROSS-REFERENCE TO RELATED APPLICATION

This application is a Bypass Continuation Application of PCT International Application No. PCT/JP2022/031442, filed on Aug. 19, 2022, the entire contents of which are incorporated herein by reference.

### BACKGROUND

### Field

The present disclosure relates to a method of processing a substrate, a method of manufacturing a semiconductor device, a substrate processing apparatus, and a recording medium.

### Description of the Related Art

As a step in a process of manufacturing a semiconductor device, a process of forming a film on a substrate may be performed.

### SUMMARY

Along with miniaturization of a semiconductor device, improvement of film quality of a film formed on a substrate is strongly required.

Some embodiments of the present disclosure provides a technique capable of improving film quality of a film formed on a substrate.

According to an embodiments of the present disclosure, there is provided a technique that includes:
forming a film containing a first element, a second element, carbon, and a halogen on a substrate by performing a cycle a predetermined number of times, the cycle including:
(a) supplying a source containing the first element, carbon, and the halogen and not containing a chemical bond between carbon and hydrogen to the substrate; and
(b) supplying a reactant containing the second element different from the first element to the substrate.

### BRIEF DESCRIPTION OF THE DRAWINGS

FIG. 1 is a schematic configuration diagram of a vertical processing furnace of a substrate processing apparatus suitably used in an embodiment of the present disclosure, and is a longitudinal cross-sectional view of a processing furnace 202.

FIG. 2 is a schematic configuration diagram of the vertical processing furnace of the substrate processing apparatus suitably used in an embodiment of the present disclosure, and is a cross-sectional view of the processing furnace 202 taken along line A-A in FIG. 1.

FIG. 3 is a schematic configuration diagram of a controller 121 of the substrate processing apparatus suitably used in an embodiment of the present disclosure, and is a block diagram illustrating a control system of the controller 121.

FIG. 4 illustrates a substrate processing sequence in an embodiment of the present disclosure.

FIG. 5A is a diagram illustrating one example of a partial structure of a molecule of a source in an embodiment of the present disclosure, and FIG. 5B is a diagram illustrating another example of a partial structure of a molecule of a source in an embodiment of the present disclosure.

### DETAILED DESCRIPTION

### Embodiment of the Present Disclosure

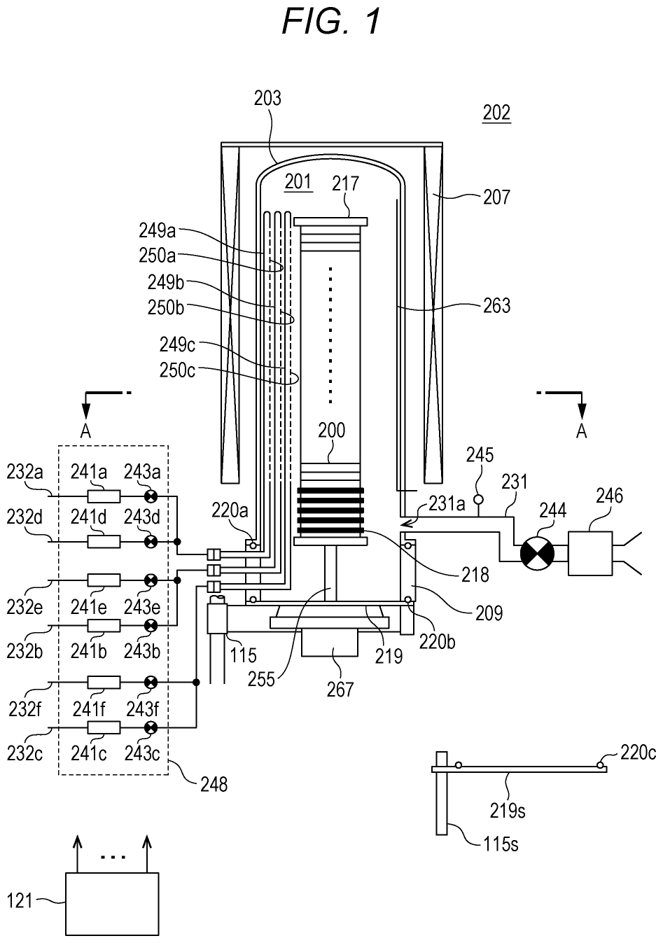

An embodiment of the present disclosure will be hereinafter described mainly with reference to FIGS. 1 to 4, 5A, and 5B. Note that the drawings used in the following description are all schematic, and dimensional relationships between elements, ratios between elements, and the like illustrated in the drawings do not necessarily coincide with actual ones. In addition, dimensional relationships between elements, ratios between elements, and the like do not necessarily coincide with each other between a plurality of drawings.

### (1) Configuration of Substrate Processing Apparatus

As illustrated in FIG. 1, a processing furnace 202 includes a heater 207 serving as a temperature regulator (heater). The heater 207 has a cylindrical shape and is supported by a holding plate to be vertically installed. The heater 207 further functions as an activating mechanism (exciter) that thermally activates (excites) gas.

Inside the heater 207, a reaction tube 203 is disposed concentrically with the heater 207. The reaction tube 203 is formed of a heat-resistant material, for example, such as quartz (SiO₂) or silicon carbide (SiC), and is formed in a cylindrical shape with an upper end closed and a lower end opened. Below the reaction tube 203, a manifold 209 is disposed concentrically with the reaction tube 203. The manifold 209 is formed of a metal material, for example, such as stainless steel (SUS), and is formed in a cylindrical shape with an upper end and lower end opened. An upper end portion of the manifold 209 is engaged with a lower end portion of the reaction tube 203 and is configured to support the reaction tube 203. An O-ring 220a serving as a seal member is provided between the manifold 209 and the reaction tube 203. The reaction tube 203 is vertically installed similarly to the heater 207. Mainly, the reaction tube 203 and the manifold 209 constitute a processing container (reaction container). A process chamber 201 is formed in a cylinder hollow portion of the processing container. The process chamber 201 is configured to be able to house a wafer 200 serving as a substrate. The wafer 200 is processed in the process chamber 201.

In the process chamber 201, nozzles 249a to 249c serving as first to third suppliers, respectively, are provided so as to penetrate a side wall of the manifold 209. The nozzles 249a to 249c are also referred to as first to third nozzles, respectively. The nozzles 249a to 249c are each formed of a heat-resistant material, for example, such as quartz or SiC. Gas supply pipes 232a to 232c are connected to the nozzles 249a to 249c, respectively. The nozzles 249a to 249c are nozzles different from one another, and the nozzles 249a and 249c are provided adjacent to the nozzle 249b.

In the gas supply pipes 232a to 232c, mass flow controllers (MFCs) 241a to 241c that are flow rate controllers and valves 243a to 243c that are opening/closing valves are provided, respectively, in this order from an upstream side of a gas flow. A gas supply pipe 232d is connected to a downstream side of the valve 243a of the gas supply pipe 232a. A gas supply pipe 232e is connected to a downstream side of the valve 243b of the gas supply pipe 232b. A gas supply pipe 232f is connected to a downstream side of the valve 243c of the gas supply pipe 232c. In the gas supply pipes 232d to 232f, MFCs 241d to 241f and valves 243d to 243f are provided, respectively, in this order from an upstream side of a gas flow. The gas supply pipes 232a to 232f are each formed of a metal material, for example, such as SUS.

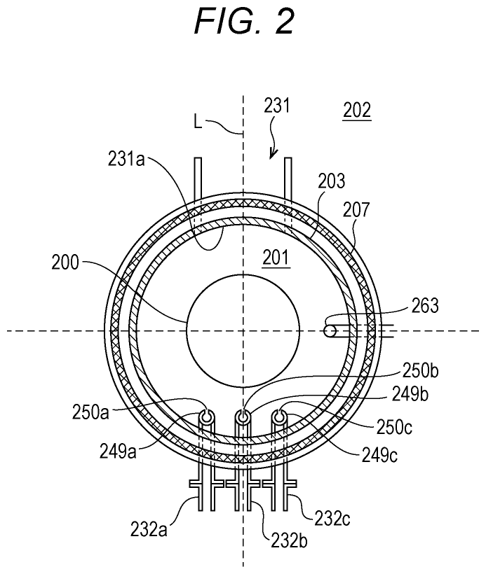

As illustrated in FIG. 2, the nozzles 249a to 249c are provided in an annular space in plan view between an inner wall of the reaction tube 203 and the wafer 200 so as to extend upward in an arrangement direction of the wafer 200 along the inner wall of the reaction tube 203 from a lower portion to an upper portion. That is, the nozzles 249a to 249c are provided along a wafer arrangement region in which the wafer 200 is arranged in a region horizontally surrounding the wafer arrangement region, on a lateral side of the wafer arrangement region. In plan view, the nozzle 249b is disposed so as to face an exhaust port 231a described later on a straight line with a center of the wafer 200 loaded into the process chamber 201 interposed therebetween. The nozzles 249a and 249c are arranged so as to interpose a straight line L passing through the nozzle 249b and a center of the exhaust port 231a from both sides along the inner wall of the reaction tube 203 (outer peripheral portion of the wafer 200). The straight line L also passes through the nozzle 249b and a center of the wafer 200. That is, it can also be said that the nozzle 249c is provided on a side opposite to the nozzle 249a with the straight line L interposed therebetween. The nozzles 249a and 249c are arranged in line symmetry with the straight line L as a symmetry axis. On side surfaces of the nozzles 249a to 249c, gas supply holes 250a to 250c through which a gas is supplied are formed, respectively. The gas supply holes 250a to 250c are each opened so as to be opposed to (face) the exhaust port 231a in plan view, and can supply gas toward the wafer 200. A plurality of the gas supply holes 250a, a plurality of the gas supply holes 250b, and a plurality of the gas supply holes 250c are formed from a lower portion to an upper portion of the reaction tube 203.

A source is supplied from the gas supply pipe 232a into the process chamber 201 via the MFC 241a, the valve 243a, and the nozzle 249a. The source is used as one of film forming agents.

A reactant is supplied from the gas supply pipe 232b into the process chamber 201 via the MFC 241b, the valve 243b, and the nozzle 249b. The reactant is used as one of the film forming agents.

A catalyst is supplied from the gas supply pipe 232c into the process chamber 201 via the MFC 241c, the valve 243c, the gas supply pipe 232c, and the nozzle 249c. The catalyst is used as one of the film forming agents.

An inert gas is supplied from the gas supply pipes 232d to 232f into the process chamber 201 via the MFCs 241d to 241f, the valves 243d to 243f, the gas supply pipes 232a to 232c, and the nozzles 249a to 249c, respectively. The inert gas acts as a purge gas, a carrier gas, a diluent gas, or the like.

Mainly, the gas supply pipe 232a, the MFC241a, and the valve 243a constitute a source supply system. Mainly, the gas supply pipe 232b, the MFC 241b, and the valve 243b constitute a reactant supply system. Mainly, the gas supply pipe 232c, the MFC 241c, and the valve 243c constitute a catalyst supply system. Mainly, the gas supply pipes 232d to 232f, the MFCs 241d to 241f, and the valves 243d to 243f constitute an inert gas supply system. Each or all of the source supply system, the reactant supply system, and the catalyst supply system is also referred to as a film forming agent supply system.

Any or all of the above-described various supply systems may be configured as an integrated supply system 248 in which the valves 243a to 243f, the MFCs 241a to 241f, and the like are integrated. The integrated supply system 248 is connected to each of the gas supply pipes 232a to 232f, and is configured such that operations of supplying various substances (various gases) into the gas supply pipes 232a to 232f, that is, opening/closing operations of the valves 243a to 243f, flow rate regulating operations by the MFCs 241a to 241f, and the like are controlled by a controller 121 described later. The integrated supply system 248 is configured as an integral or separable integrated unit, and can be attached to and detached from the gas supply pipes 232a to 232f and the like in units of integrated units. Maintenance, replacement, expansion, and the like of the integrated supply system 248 can be performed in units of integrated units.

Below a side wall of the reaction tube 203, the exhaust port 231a from which an atmosphere inside the process chamber 201 is exhausted is formed. As illustrated in FIG. 2, the exhaust port 231a is formed at a location opposite to (facing) the nozzles 249a to 249c (gas supply holes 250a to 250c) with the wafer 200 interposed therebetween in plan view. The exhaust port 231a may be formed along a side wall of the reaction tube 203 from a lower portion to an upper portion, that is, along the wafer arrangement region. An exhaust pipe 231 is connected to the exhaust port 231a. A vacuum pump 246 serving as a vacuum-exhaust device is connected to the exhaust pipe 231 via a pressure sensor 245 serving as a pressure detector that detects a pressure in the process chamber 201 and an auto pressure controller (APC) valve 244 serving as a pressure regulator. The APC valve 244 is configured to be able to perform vacuum exhaust and stop the vacuum exhaust inside the process chamber 201 by opening and closing the valve in a state where the vacuum pump 246 is operated, and to be able to regulate a pressure in the process chamber 201 by regulating the degree of valve opening on the basis of pressure information detected by the pressure sensor 245 in a state where the vacuum pump 246 is operated. Mainly, the exhaust pipe 231, the APC valve 244, and the pressure sensor 245 constitute an exhaust system. The vacuum pump 246 may be included in the exhaust system.

Below the manifold 209, a seal cap 219 serving as a furnace lid capable of airtightly closing a lower end opening of the manifold 209 is provided. The seal cap 219 is formed of a metal material, for example, such as SUS, and is formed in a disk shape. On an upper surface of the seal cap 219, an O-ring 220b serving as a seal member that is in contact with a lower end of the manifold 209 is provided. Below the seal cap 219, a rotation mechanism 267 that rotates a boat 217 described later is disposed. A rotating shaft 255 of the rotation mechanism 267 penetrates the seal cap 219 and is connected to the boat 217. The rotation mechanism 267 is configured to rotate the wafer 200 by rotating the boat 217. The seal cap 219 is configured to be lifted up and down in a vertical direction by a boat elevator 115 serving as a lifting mechanism disposed outside the reaction tube 203. The boat elevator 115 is configured as a transfer device (transfer mechanism) that lifts the seal cap 219 up and down, thereby loading and unloading (transferring) the wafer 200 into/from the process chamber 201.

Below the manifold 209, a shutter 219s serving as a furnace opening lid capable of airtightly closing a lower end opening of the manifold 209 in a state where the seal cap 219 is lowered to unload the boat 217 out of the process chamber 201 is provided. The shutter 219s is formed of a metal material, for example, such as SUS, and is formed in a disk shape. On an upper surface of the shutter 219s, an O-ring 220c serving as a seal member that is in contact with a lower end of the manifold 209 is provided. An opening/closing operation (lifting operation, rotating operation, and the like) of the shutter 219s is controlled by a shutter opening/closing mechanism 115s.

The boat 217 serving as a substrate support tool is configured to support a plurality of, for example, 25 to 200 wafers 200 in multiple stages, that is, to arrange the wafers 200 at intervals, while the wafers 200 are aligned in the vertical direction in a horizontal posture in a state where centers thereof are aligned with each another. The boat 217 is formed of a heat-resistant material, for example, such as quartz or SiC. Heat insulating plates 218 each formed of a heat-resistant material, for example, such as quartz or SiC are supported in multiple stages in a lower portion of the boat 217.

In the reaction tube 203, a temperature sensor 263 serving as a temperature detector is disposed. By regulating the degree of energization to the heater 207 on the basis of temperature information detected by the temperature sensor 263, a desired temperature distribution can be achieved in the process chamber 201. The temperature sensor 263 is provided along an inner wall of the reaction tube 203.

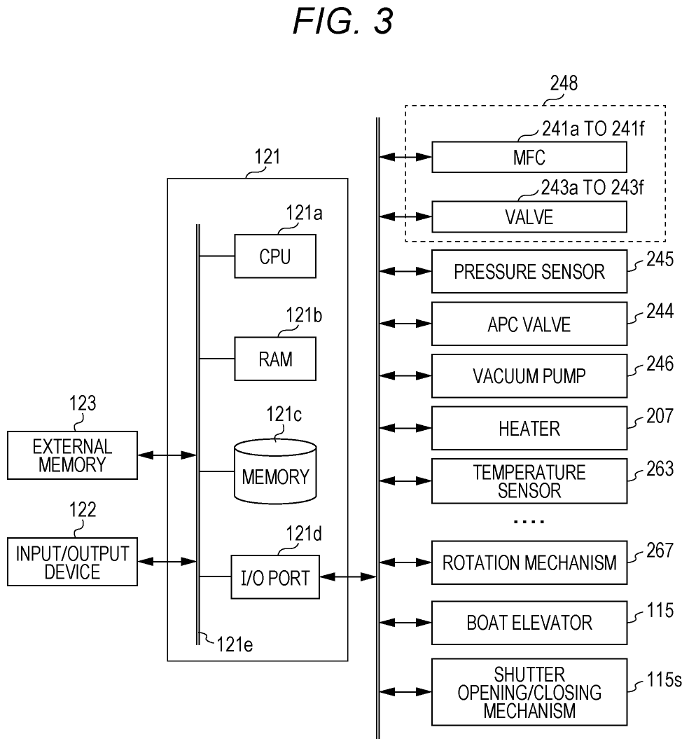

As illustrated in FIG. 3, a controller 121 serving as a controller is configured as a computer including a central processing unit (CPU) 121a, a random access memory (RAM) 121b, a memory 121c, and an I/O port 121d. The RAM 121b, the memory 121c, and the I/O port 121d are configured to be able to exchange data with the CPU 121a via an internal bus 121e. An input/output device 122 configured as, for example, a touch panel is connected to the controller 121. In addition, an external memory 123 can be connected to the controller 121.

The memory 121c includes, for example, a flash memory, a hard disk drive (HDD), and a solid state drive (SSD). In the memory 121c, a control program that controls operation of a substrate processing apparatus, a process recipe in which procedures, conditions, and the like of substrate processing described later are described, and the like are readably recorded and stored. The process recipe is a combination formed such that the controller 121 causes the substrate processing apparatus to execute each procedure in substrate processing described later to obtain a predetermined result, and functions as a program. Hereinafter, the process recipe, the control program, and the like are collectively and simply referred to as a program. The process recipe is simply referred to as a recipe. In a case where the term “program” is used in the present specification, this might include a case where only the recipe alone is included, a case where only the control program alone is included, or a case where both of them are included. The RAM 121b is configured as a memory area (work area) in which a program, data, and the like read by the CPU 121a are temporarily stored.

The I/O port 121d is connected to the MFCs 241a to 241f, the valves 243a to 243f, the pressure sensor 245, the APC valve 244, the vacuum pump 246, the temperature sensor 263, the heater 207, the rotation mechanism 267, the boat elevator 115, the shutter opening/closing mechanism 115s, and the like described above.

The CPU 121a is configured to be able to read and execute a control program from the memory 121c, and to read a recipe from the memory 121c in response to an input and the like of an operation command from the input/output device 122. The CPU 121a is configured to be able to control, in accordance with a content of the read recipe, a flow rate regulating operation of various substances (various gases) by the MFCs 241a to 241f, an opening/closing operation of the valves 243a to 243f, a pressure regulating operation by the APC valve 244 based on an opening/closing operation of the APC valve 244 and the pressure sensor 245, start and stop of the vacuum pump 246, a temperature regulating operation of the heater 207 based on the temperature sensor 263, a rotation and rotating speed regulating operation of the boat 217 by the rotation mechanism 267, a lifting operation of the boat 217 by the boat elevator 115, an opening/closing operation of the shutter 219s by the shutter opening/closing mechanism 115s, and the like.

The controller 121 can be configured by installing the above-described program recorded and stored in the external memory 123 into a computer. Examples of the external memory 123 include a magnetic disk such as an HDD, an optical disk such as a CD, a magneto-optical disk such as an MO, and a semiconductor memory such as a USB memory or an SSD. The memory 121c and the external memory 123 are configured as computer-readable recording media. Hereinafter, these are also collectively and simply referred to as a recording medium. In the present specification, the term “recording medium” may include the memory 121c alone, may include the external memory 123 alone, or may include both of these. Note that the program may be provided to the computer by using a communication means such as the Internet or a dedicated line without using the external memory 123.

### (2) Substrate Processing Step

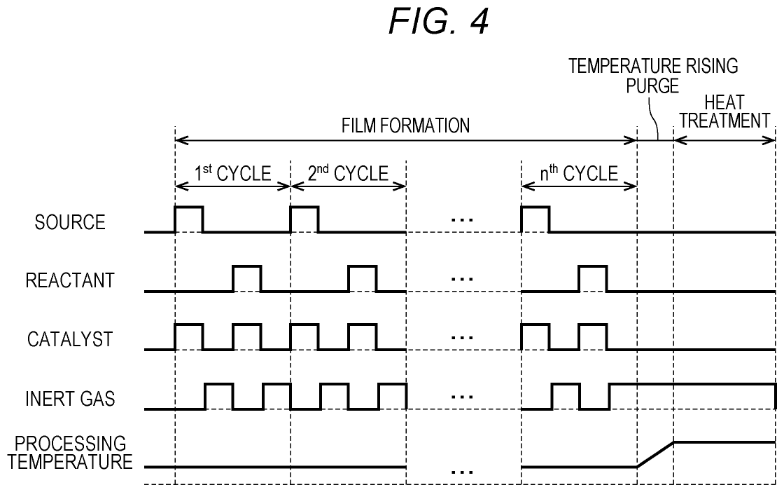

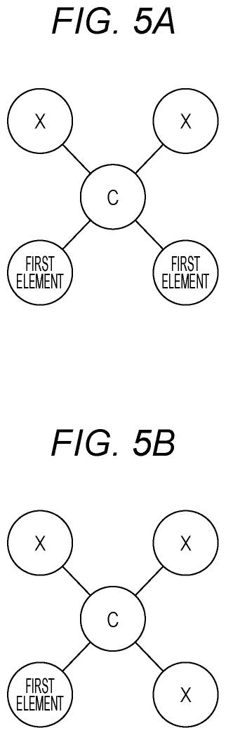

As a step in a process of manufacturing a semiconductor device using the substrate processing apparatus described above, an example of a method of processing a substrate, that is, a processing sequence of forming a film on the wafer 200 serving as a substrate will be described mainly with reference to FIGS. 4, 5A, and 5B. In the following description, an operation of each unit included in the substrate processing apparatus is controlled by the controller 121.

In a processing sequence in the present embodiment, by performing a cycle including:
(a) a step of supplying a source containing a first element, carbon, and a halogen and not containing a chemical bond between carbon and hydrogen to the wafer 200 (source supply step); and
(b) a step of supplying a reactant containing a second element different from the first element to the wafer 200 (reactant supply step)
a predetermined number of times (n times, n is an integer of 1 or more), a step of forming a film containing the first element, the second element, carbon, and the halogen (film forming step) on the wafer 200 is performed. Each step is performed in a non-plasma atmosphere.

In the following example, as illustrated in FIG. 4, a case where a catalyst is further supplied to the wafer 200 in at least one of the source supply step and the reactant supply step will be described. FIG. 4 illustrates an example in which a catalyst is further supplied to the wafer 200 in both the source supply step and the reactant supply step as a representative example.

In the present specification, the above-described processing sequence may be expressed as follows for convenience. A similar expression will be used in the following description of modified examples, other embodiments, and the like.

$$( source + catalyst \to reactant + catalyst ) \times n$$

Note that, as in the following processing sequence, a catalyst may be further supplied to the wafer 200 in at least one of the source supply step and the reactant supply step.

$$( source + catalyst \to reactant ) \times n$$

$$( source \to reactant + catalyst ) \times n$$

$$( source + catalyst \to reactant + catalyst ) \times n$$

In addition, as in the processing sequence illustrated in FIG. 4 or the following, after the film forming step is performed, a step of heat-treating the wafer 200 (heat treatment step) may be further performed.

$$( source + catalyst \to reactant ) \times n \to heat treatment$$

$$( source + catalyst \to reactant + catalyst ) \times n \to heat treatment$$

$$( source + catalyst \to reactant + catalyst ) \times n \to heat treatment$$

The term “wafer” used in the present specification may mean a wafer itself, or a laminate of a wafer and a predetermined layer or film formed on a surface thereof. The phrase “surface of a wafer” used in the present specification may mean a surface of a wafer itself or a surface of a predetermined layer or the like formed on a wafer. In the present specification, the phrase “forming a predetermined layer on a wafer” means directly forming a predetermined layer on a surface of a wafer itself, or forming a predetermined layer on a layer or the like formed on a wafer. The term “substrate” in the present specification is synonymous with the term “wafer”.

The term “agent” used in the present specification includes at least one of a gaseous substance and a liquid substance. The liquid substance includes a mist substance. That is, the film forming agents (a source, a reactant, and a catalyst) may each contain a gaseous substance, a liquid substance such as a mist substance, or both of these.

The term “layer” used in the present specification includes at least one of a continuous layer and a discontinuous layer. A layer formed in each step described later may include a continuous layer, a discontinuous layer, or both of these.

### (Wafer Charge and Boat Load)

When a plurality of wafers 200 is loaded on the boat 217 (wafer charge), the shutter opening/closing mechanism 115s moves the shutter 219s, and a lower end opening of the manifold 209 is opened (shutter open). Thereafter, as illustrated in FIG. 1, the boat 217 supporting the plurality of wafers 200 is elevated by the boat elevator 115 and is loaded into the process chamber 201 (boat load). In this state, the seal cap 219 seals a lower end of the manifold 209 via the O-ring 220b. In this manner, the wafers 200 are prepared in the process chamber 201.

### (Pressure Regulation and Temperature Regulation)

After the boat load is finished, the inside of the process chamber 201, that is, a space in which the wafers 200 are present is vacuum-exhausted (decompression-exhausted) by the vacuum pump 246 so as to achieve a desired pressure (vacuum degree). At this time, the pressure sensor 245 measures a pressure in the process chamber 201, and the APC valve 244 is feedback-controlled on the basis of the measured pressure information. In addition, the heater 207 heats the wafer 200 in the process chamber 201 such that a temperature of the wafer 200 reaches a desired processing temperature. At this time, the degree of energization to the heater 207 is feedback-controlled on the basis of the temperature information detected by the temperature sensor 263 such that the inside of the process chamber 201 has a desired temperature distribution. In addition, rotation of the wafer 200 by the rotation mechanism 267 is started. Exhaust in the process chamber 201, heating and rotation of the wafer 200 continue at least until processing on the wafer 200 is finished.

### (Film Forming Step)

Thereafter, the following source supply step and reactant supply step are sequentially executed.

### [Source Supply Step]

In this step, a source (source gas) and a catalyst (catalyst gas) are supplied to the wafer 200 as film forming agents.

Specifically, the valves 243a and 243c are opened to allow the source and the catalyst to flow into the gas supply pipes 232a and 232c, respectively. The source and the catalyst of which flow rates are regulated by the MFCs 241a and 241c, respectively, are supplied into the process chamber 201 via the nozzles 249a and 249c, respectively, mixed in the process chamber 201, and discharged from the exhaust port 231a. At this time, the source and the catalyst are supplied from a lateral side of the wafer 200 to the wafer 200 (source+catalyst supply). At this time, the valves 243d to 243f may be opened to supply an inert gas into the process chamber 201 via the nozzles 249a to 249c, respectively.

By supplying the source and the catalyst to the wafer 200 under processing conditions described later, a first layer is formed on the wafer 200. The first layer is a layer containing the first element, carbon, and a halogen.

In this step, by supplying the catalyst together with the source, the above-described reaction can be allowed to proceed in a non-plasma atmosphere or under a low temperature condition as described later. As a result, it is possible to suppress thermal decomposition (gas phase decomposition), that is, self-decomposition of the source in the process chamber 201, to hold at least a part of a chemical bond in the source without breaking the chemical bond, and to hold at least a part of a partial structure of a molecule of the source without breaking the partial structure when the above-described reaction is allowed to proceed. The first layer is a layer containing at least a part of the chemical bond in the source and containing at least a part of the partial structure of the molecule of the source.

Note that since the source used in this step does not contain a chemical bond between carbon and hydrogen, the first layer is a layer not substantially containing a chemical bond between carbon and hydrogen, that is, a layer not containing a chemical bond between carbon and hydrogen.

Processing conditions when the source and the catalyst are supplied in the source supply step are exemplified as follows:
processing temperature: room temperature (25° C.) to 200° C., preferably room temperature to 150° C.
processing pressure: 133 to 1333 Pa
source supply flow rate: 0.001 to 2 slm
catalyst supply flow rate: 0.001 to 2 slm
inert gas supply flow rate (per gas supply pipe): 0 to 20 slm
each gas supply time: 1 to 120 seconds, preferably 1 to 60 seconds

Note that expression of a numerical range such as “133 to 1333 Pa” in the present specification means that the lower limit and the upper limit are included in the range. Therefore, for example, “133 to 1333 Pa” means “133 Pa or more and 1333 Pa or less”. The same applies to other numerical ranges. The processing temperature in the present specification means a temperature of the wafer 200 or a temperature in the process chamber 201, and the processing pressure means a pressure in the process chamber 201. The processing time means a time during which the processing is continued. When 0 slm is included in the supply flow rate, “0 slm” means a case where the substance (gas) is not supplied. The same applies to the following description.

After the first layer is formed on the wafer 200, the valves 243a and 243c are closed to stop supply of the source and the catalyst into the process chamber 201. Then, the inside of the process chamber 201 is vacuum-exhausted to remove a gaseous substance and the like remaining in the process chamber 201 from the inside of the process chamber 201. At this time, the valves 243d to 243f are opened to supply an inert gas into the process chamber 201 via the nozzles 249a to 249c. The inert gas supplied from the nozzles 249a to 249c acts as a purge gas, whereby the inside of the process chamber 201 is purged (purge). A processing temperature when purge is performed in this step is preferably similar to the processing temperature at the time of supplying the source and the catalyst.

As the source, for example, a substance containing the first element, carbon (C), and a halogen and not containing a chemical bond between carbon (C) and hydrogen (H) can be used. The first element includes, for example, silicon (Si). The halogen includes chlorine (Cl), fluorine (F), bromine (Br), iodine (I), and the like.

The source may contain a chemical bond between the first element and carbon and a chemical bond between the halogen and carbon. By using such a substance as the source, the first layer can contain these chemical bonds in the source, that is, a chemical bond between the first element and carbon and a chemical bond between the halogen and carbon.

A molecule of the source may include a partial structure in which a halogen atom is bonded to each of at least two bonds among four bonds of a carbon atom, and an atom of the first element is bonded to each of the remaining bonds.

For example, as illustrated in FIG. 5A, the molecule of the source may include a partial structure in which an atom of a halogen (X) is bonded to each of two bonds among four bonds of an atom of carbon (C), and an atom of the first element is bonded to each of the remaining two bonds. For example, as illustrated in FIG. 5B, the molecule of the source may include a partial structure in which an atom of a halogen (X) is bonded to each of three bonds among four bonds of an atom of carbon (C), and an atom of the first element is bonded to the remaining one bond.

By using these substances as the source, the first layer can include the above-described partial structures, that is, the partial structure illustrated in FIG. 5A or 5B.

As the source, for example, bistrichlorosilyl difluoromethane (Cl₃Si—CF₂—SiCl₃), bistrichlorosilyl dichloromethane (Cl₃Si—CCl₂—SiCl₃), trifluoromethyltrichlorosilane (Cl₃Si—CF₃), or trichloromethyltrichlorosilane (Cl₃Si—CCl₃) can be used.

Cl₃Si—CF₂—SiCl₃ contains Si, C, F, and Cl, does not contain a C—H bond, and contains a Si—C—Si bond and an F—C bond. This molecule includes a partial structure of the type illustrated in FIG. 5A, that is, a partial structure (Si—CF₂—Si) in which F is bonded to each of two bonds among four bonds of C located at a center of a Si—C—Si bond, and Si is bonded to each of the remaining two bonds. By using such a substance as the source, it is possible to form a layer containing Si and C, containing F as a halogen, and not containing a C—H bond as the first layer. In addition, the first layer can contain a chemical bond (a Si—C—Si bond and an F—C bond) in the source and contain a partial structure (Si—CF₂—Si) of a molecule of the source.

Cl₃Si—CCl₂—SiCl₃ contains Si, C, and Cl, does not contain a C—H bond, and contains a Si—C—Si bond and a Cl—C bond. This molecule includes a partial structure of the type illustrated in FIG. 5B, that is, a partial structure (Si—CCl₂—Si) in which Cl is bonded to each of two bonds among four bonds of C located at a center of a Si—C—Si bond, and Si is bonded to each of the remaining two bonds. By using such a substance as the source, it is possible to form a layer containing Si and C, containing Cl as a halogen, and not containing a C—H bond as the first layer. In addition, the first layer can contain a chemical bond (a Si—C—Si bond and a Cl—C bond) in the source and contain a partial structure (Si—CCl₂—Si) of a molecule of the source.

Cl₃Si—CF₃ contains Si, C, F, and Cl, does not contain a C—H bond, and contains a Si—C bond and an F—C bond. This molecule includes a partial structure of the type illustrated in FIG. 5B, that is, a partial structure (Si—CF₃) in which F is bonded to each of three bonds among four bonds of C contained in a Si—C bond, and Si is bonded to the remaining one bond. By using such a substance as the source, it is possible to form a layer containing Si and C, containing F as a halogen, and not containing a C—H bond as the first layer. In addition, the first layer can contain a chemical bond (a Si—C bond and an F—C bond) in the source and contain a partial structure (Si—CF₃) of a molecule of the source.

Cl₃Si—CCl₃ contains Si, C, and Cl, does not contain a C—H bond, and contains a Si—C bond and a Cl—C bond. This molecule includes a partial structure of the type illustrated in FIG. 5B, that is, a partial structure (Si—CCl₃) in which Cl is bonded to each of three bonds among four bonds of C contained in a Si—C bond, and Si is bonded to the remaining one bond. By using such a substance as the source, it is possible to form a layer containing Si and C, containing Cl as a halogen, and not containing a C—H bond as the first layer. In addition, the first layer can contain a chemical bond (a Si—C bond and a Cl—C bond) in the source and contain a partial structure (Si—CCl₃) of a molecule of the source.

One or more of these can be used as the source. Note that, in these substances exemplified as the source, Cl is bonded to each of the remaining three bonds that are not bonded to C among four bonds of Si contained in the partial structure of the molecule of the source, but the source that can be used in the present disclosure is not limited to these substances. That is, a halogen (F or the like) other than Cl may be bonded to at least one of the remaining three bonds that are not bonded to C among four bonds of Si contained in the partial structure, or an element (H or the like) other than a halogen may be bonded thereto.

As the catalyst, for example, an amine-based gas (amine-based substance) containing carbon (C), nitrogen (N), and hydrogen (H) can be used. As the amine-based gas (amine-based substance), a cyclic amine-based gas (cyclic amine-based substance) or a chain amine-based gas (chain amine-based substance) can be used. As the catalyst, for example, cyclic amines such as pyridine (C₅H₅N), aminopyridine (C₅H₆N₂), picoline (C₆H₇N), lutidine (C₇H₉N), pyrimidine (C₄H₄N₂), quinoline (C₉H₇N), piperazine (C₄HioN₂), piperidine (C₅Hu₁N), and aniline (C₆H₇N) can be used. As the catalyst, for example, chain amines such as triethylamine ((C₂H₅)₃N, abbreviation: TEA), diethylamine ((C₂H₅)₂NH, abbreviation: DEA), monoethylamine ((C₂H₅)NH₂, abbreviation: MEA), trimethylamine ((CH₃)₃N, abbreviation: TMA), dimethylamine ((CH₃)₂NH, abbreviation: DMA), and monomethylamine ((CH₃)NH₂, abbreviation: MMA) can be used. One or more of these can be used as the catalyst. The same applies to the reactant supply step described later.

As the inert gas, a nitrogen (N₂) gas or a rare gas such as an argon (Ar) gas, a helium (He) gas, a neon (Ne) gas, or a xenon (Xe) gas can be used. One or more of these gases can be used as the inert gas. The same applies to each step described later.

### [Reactant Supply Step]

After the source supply step is finished, a reactant (reactant gas) and a catalyst (catalyst gas) are supplied as film forming agents to the wafer 200, that is, to the wafer 200 on which the first layer has been formed. Here, an example will be described in which an oxidant (oxidizing gas) containing oxygen serving as the second element different from the first element is used as the reactant (reactant gas).

Specifically, the valves 243b and 243c are opened to allow the reactant and the catalyst to flow into the gas supply pipes 232b and 232c, respectively. The reactant and the catalyst of which flow rates are regulated by the MFCs 241b and 241c, respectively, are supplied into the process chamber 201 via the nozzles 249b and 249c, respectively, mixed in the process chamber 201, and discharged from the exhaust port 231a. At this time, the reactant and the catalyst are supplied from a lateral side of the wafer 200 to the wafer 200 (reactant+catalyst supply). At this time, the valves 243d to 243f may be opened to supply an inert gas into the process chamber 201 via the nozzles 249a to 249c, respectively.

By supplying the reactant and the catalyst to the wafer 200 under processing conditions described later, at least a part of the first layer formed on the wafer 200 in the source supply step can be oxidized. As a result, a second layer formed by oxidizing the first layer is formed on the wafer 200. The second layer is a layer containing the first element, oxygen serving as the second element, carbon, and a halogen.

In this step, by supplying the catalyst together with the reactant, the above-described reaction can be allowed to proceed in a non-plasma atmosphere and under a low temperature condition as described later. As a result, when the above-described reaction is allowed to proceed, it is possible to hold at least a part of the above-described chemical bond (the above-described chemical bond in the source) contained in the first layer without breaking the chemical bond, and to hold at least a part of the above-described partial structure (the above-described partial structure in the molecule of the source) contained in the first layer without breaking the partial structure. As a result, the second layer is a layer containing at least a part of the above-described chemical bond in the source and containing at least a part of the above-described partial structure in the molecule of the source.

Note that, in this step, when the above-described reaction is allowed to proceed, at least a part of the above-described chemical bond (the above-described chemical bond in the source) contained in the first layer is held without being broken, and at least a part of the above-described partial structure (the above-described partial structure in the molecule of the source) contained in the first layer is held without being broken, whereby introduction of a chemical bond between carbon and hydrogen into the second layer can be suppressed. The second layer is a layer having a small number of chemical bonds between carbon and hydrogen, and is a layer not containing a chemical bond between carbon and hydrogen as in the first layer depending on processing conditions in this step and an oxidant used in this step.

Processing conditions when the reactant and the catalyst are supplied in the reactant supply step are exemplified as follows:
processing temperature: room temperature (25° C.) to 200° C., preferably room temperature to 150° C.
processing pressure: 133 to 1333 Pa
reactant supply flow rate: 0.001 to 2 slm
catalyst supply flow rate: 0.001 to 2 slm
inert gas supply flow rate (per gas supply pipe): 0 to 20 slm
each gas supply time: 1 to 120 seconds, preferably 1 to 60 seconds

After the first layer formed on the wafer 200 is oxidized and changed (converted) to the second layer, the valves 243b and 243c are closed to stop supply of the reactant and the catalyst into the process chamber 201. Then, according to processing procedures and processing conditions similar to those for the purge in the source supply step, the gaseous substance or the like remaining in the process chamber 201 is removed from the inside of the process chamber 201 (purge). A processing temperature when purge is performed in this step is preferably similar to the processing temperature when the reactant and the catalyst are supplied.

As the reactant, that is, the oxidant, for example, an oxygen (O) and hydrogen (H)-containing gas (O and H-containing substance) can be used. As the O and H-containing gas, for example, water vapor (H₂O gas), a hydrogen peroxide (H₂O₂) gas, a hydrogen (H₂) gas+an oxygen (O₂) gas, or a H₂ gas+an ozone (O₃) gas can be used. That is, as the O and H-containing gas, an O-containing gas+an H-containing gas can also be used. In this case, as the H-containing gas, that is, a reducing gas, a deuterium (D₂) gas can also be used instead of a H₂ gas. One or more of these can be used as the reactant.

Note that description of two gases such as “H₂ gas+O₂ gas” in the present specification means a mixed gas of a H₂ gas and an O₂ gas. In a case of supplying a mixed gas, two gases may be mixed (premixed) in a supply pipe and then supplied into the process chamber 201, or the two gases may be separately supplied into the process chamber 201 from different supply pipes and mixed (post-mixed) in the process chamber 201.

In addition, as the reactant, that is, the oxidant, an O-containing gas (O-containing substance) can be used in addition to the O and H-containing gas. As the O-containing gas, for example, an O₂ gas, an O₃ gas, a nitrous oxide (N₂O) gas, a nitrogen monoxide (NO) gas, a nitrogen dioxide (NO₂) gas, a carbon monoxide (CO) gas, or a carbon dioxide (CO₂) gas can be used. One or more of these can be used as the reactant.

As the catalyst, for example, a catalyst similar to the various catalysts exemplified in the above-described source supply step can be used.

### [Predetermined Number of Times of Execution]

By performing a cycle in which the source supply step and the reactant supply step described above are performed not simultaneously, that is, not synchronously but alternately, a predetermined number of times (n times, n is an integer of 1 or more), a film containing the first element, the second element, carbon, and a halogen can be formed as a film on the wafer 200.

This film is a film containing at least a part of a chemical bond in the source. When the source contains a chemical bond between the first element and carbon and a chemical bond between a halogen and carbon, the film formed on the wafer 200 is a film containing the chemical bond between the first element and carbon and the chemical bond between the halogen and carbon.

In addition, this film is a film containing at least a part of a partial structure of a molecule of the source. When the molecule of the source includes a partial structure in which a halogen atom is bonded to each of at least two bonds among four bonds of a carbon atom and an atom of the first element is bonded to each of the remaining bonds, the film formed on the wafer 200 is a film including this partial structure, that is, the partial structure illustrated in FIG. 5A or 5B.

As described above, the first layer is a layer not containing a chemical bond between carbon and hydrogen. The second layer is a layer having a small number of chemical bonds between carbon and hydrogen or a layer not containing a chemical bond between carbon and hydrogen as in the first layer. From these, the film formed on the wafer 200 is a film having a small number of chemical bonds between carbon and hydrogen or a film not containing a chemical bond between carbon and hydrogen.

When Cl₃Si—CF₂—SiCl₃ containing Si as the first element is used as the source, the above-described oxidant containing O as the second element is used as the reactant, and the above-described catalyst is used, a film containing Si, O, and C and containing F as a halogen, that is, a silicon oxycarbide film (SiOC film) containing F can be formed as a film on the wafer 200. This film is a film containing a chemical bond (a Si—C—Si bond and an F—C bond) in the source and containing a partial structure (Si—CF₂—Si) of a molecule of the source. This film is a film having a small number of C—H bonds or a film containing no C—H bond.

When Cl₃Si—CCl₂—SiCl₃ containing Si as the first element is used as the source, the above-described oxidant containing O as the second element is used as the reactant, and the above-described catalyst is used, a film containing Si, O, and C and containing Cl as a halogen, that is, a SiOC film containing Cl can be formed as a film on the wafer 200. This film is a film containing a chemical bond (a Si—C—Si bond and a Cl—C bond) in the source and containing a partial structure (Si—CCl₂—Si) of a molecule of the source. This film is a film having a small number of C—H bonds or a film containing no C—H bond.

When Cl₃Si—CF₃ containing Si as the first element is used as the source, the above-described oxidant containing O as the second element is used as the reactant, and the above-described catalyst is used, a film containing Si, O, and C and containing F as a halogen, that is, a SiOC film containing F can be formed as a film on the wafer 200. This film is a film containing a chemical bond (a Si—C bond and an F—C bond) in the source and containing a partial structure (Si—CF₃) of a molecule of the source. This film is a film having a small number of C—H bonds or a film containing no C—H bond.

When Cl₃Si—CCl₃ containing Si as the first element is used as the source, the above-described oxidant containing O as the second element is used as the reactant, and the above-described catalyst is used, a film containing Si, O, and C and containing Cl as a halogen, that is, a SiOC film containing Cl can be formed as a film on the wafer 200. This film is a film containing a chemical bond (a Si—C bond and a Cl—C bond) in the source and containing a partial structure (Si—CCl₃) of a molecule of the source. This film is a film having a small number of C—H bonds or a film containing no C—H bond.

The cycle described above is preferably repeated a plurality of times. That is, it is preferable to repeat the above-described cycle a plurality of times until the thickness of the second layer formed per cycle is smaller than a desired thickness and the thickness of the film formed by laminating the second layer is a desired thickness.

### (Heat Treatment Step)

After the film forming step is performed, heat treatment is performed on the wafer 200 on which a film has been formed. At this time, output of the heater 207 is adjusted such that a temperature in the process chamber 201, that is, a temperature of the wafer 200 on which a film has been formed is equal to or higher than the temperature of the wafer 200 in the film forming step.

By performing heat treatment (annealing) on the wafer 200, it is possible to remove impurities contained in the film formed on the wafer 200 in the film forming step and to repair defects, and it is possible to harden the film. By hardening the film, processing resistance of the film, that is, etching resistance can be improved. Note that, in the film formed on the wafer 200, in a case where removal of impurities, repair of defects, hardening of the film, or the like is unnecessary, the annealing, that is, the heat treatment step can be omitted.

Note that this step may be performed in a state where an inert gas is supplied into the process chamber 201, or may be performed in a state where a reactive substance such as an oxidant (oxidizing gas) is supplied. In this case, the inert gas or the reactive substance such as an oxidant (oxidizing gas) is also referred to as an assist substance.

Processing conditions when the heat treatment is performed in the heat treatment step are exemplified as follows:
processing temperature: 200° C. to 1000° C., preferably 400° C. to 700° C.
processing pressure: 1 to 120000 Pa
processing time: 1 to 18000 seconds
assist substance supply flow rate (per gas supply pipe): 0 to 50 slm.

### (After-Purge and Atmospheric Pressure Restoration)

After the heat treatment step is finished, an inert gas serving as a purge gas is supplied from each of the nozzles 249a to 249c into the process chamber 201 and is discharged from the exhaust port 231a. As a result, the inside of the process chamber 201 is purged, and a gas and a reaction by-product remaining in the process chamber 201 are removed from the inside of the process chamber 201 (after-purge). Thereafter, the atmosphere in the process chamber 201 is replaced with the inert gas (inert gas replacement), and the pressure in the process chamber 201 is restored to a normal pressure (atmospheric pressure restoration).

### (Boat Unload and Wafer Discharge)

Thereafter, the boat elevator 115 lowers the seal cap 219 to open a lower end of the manifold 209. Then, the processed wafer 200 is unloaded from the lower end of the manifold 209 to the outside of the reaction tube 203 in a state of being supported by the boat 217 (boat unload). After the boat unload, the shutter 219s is moved, and the lower end opening of the manifold 209 is sealed by the shutter 219s via the O-ring 220c (shutter close). After being unloaded to the outside of the reaction tube 203, the processed wafer 200 is taken out from the boat 217 (wafer discharge).

The film forming step and the heat treatment step are preferably performed in the same process chamber (in-situ). As a result, the film forming step and the heat treatment step can be performed without exposing the wafer 200 to the atmosphere, that is, while maintaining a surface of the wafer 200 in a clean state. By performing these steps in the same process chamber, it is possible to avoid deterioration of film quality of a film formed on the wafer 200.

### (3) Effects of Present Embodiment

According to the present embodiment, one more effects described below can be obtained.

(a) By performing a cycle including: a source supply step of supplying a source containing a first element, carbon, and a halogen and not containing a chemical bond between carbon and hydrogen; and a reactant supply step of supplying a reactant containing a second element different from the first element a predetermined number of times, film quality of a film formed on the wafer 200, that is, a film containing the first element, the second element, carbon, and the halogen can be improved.

That is, according to the present embodiment, by using a source containing the first element, carbon, and a halogen and not containing a chemical bond between carbon and hydrogen, it is possible to reduce the number of chemical bonds between carbon and hydrogen in a film formed on the wafer 200 without excessively increasing the number of chemical bonds between the first element and carbon in the film. As a result, it is possible to suppress desorption of carbon from the film due to oxidation while appropriately maintaining the number of the chemical bonds between the first element and carbon in the film. As a result, it is possible to improve ashing resistance (oxidation resistance and plasma oxidation resistance) which is one of processing resistance of a film formed on the wafer 200 while suppressing an increase in relative permittivity (k value) due to an increase in density of the film. That is, it is possible to achieve both a decrease in dielectric constant (low-k) of the film and an improvement of ashing resistance, which are in a relationship of trade-off. In addition, etching resistance (wet etching resistance), which is one of processing resistance of the film before and after ashing, can also be improved.

Note that it is possible to form a film containing the first element, the second element, carbon, and fluorine by a method of forming a film using a source containing a chemical bond between the first element and carbon and a chemical bond between carbon and hydrogen, a reactant containing the second element, and a catalyst and modifying the film using a fluorine-based gas. However, in this method, since the source contains a chemical bond between carbon and hydrogen, it is difficult to obtain the above-described effect. In addition, etching of the film may occur depending on processing conditions.

(b) In the source supply step, by supplying a source containing a chemical bond between the first element and carbon and a chemical bond between a halogen and carbon, these chemical bonds can be contained in the film formed on the wafer 200. As a result, it is possible to further improve the ashing resistance of the film while suppressing an increase in the k value of the film. In addition, the etching resistance of the film before and after ashing can be further improved.

(c) When a molecule of the source supplied in the source supply step includes the above-described partial structure in which a halogen atom is bonded to each of at least two bonds among four bonds of a carbon atom and an atom of the first element is bonded to each of the remaining bonds, the film formed on the wafer 200 can include this partial structure. As a result, it is possible to further improve the ashing resistance of the film while suppressing an increase in the k value of the film. In addition, the etching resistance of the film before and after ashing can be further improved.

For example, when the molecule of the source supplied in the source supply step includes a partial structure of the type illustrated in FIG. 5A, that is, a partial structure in which a halogen atom is bonded to each of two bonds among four bonds of a carbon atom and an atom of the first element is bonded to each of the remaining two bonds, the film formed on the wafer 200 can include this partial structure. For example, when Cl₃Si—CF₂—SiCl₃ is supplied as the source, it is possible to form a film containing Si as the first element, F as a halogen, and Si—CF₂—Si as the above-described partial structure on the wafer 200. In addition, for example, when Cl₃Si—CCl₂—SiCl₃ is supplied as the source, it is possible to form a film containing Si as the first element, Cl as a halogen, and Si—CCl₂—Si as the above-described partial structure on the wafer 200. In these cases, it is possible to sufficiently improve the ashing resistance of the film while sufficiently suppressing an increase in the k value of the film. In addition, the etching resistance of the film before and after ashing can be sufficiently improved.

For example, when the molecule of the source supplied in the source supply step includes a partial structure of the type illustrated in FIG. 5B, that is, a partial structure in which a halogen atom is bonded to each of three bonds among four bonds of a carbon atom and an atom of the first element is bonded to the remaining one bond, the film formed on the wafer 200 can include this partial structure. For example, when Cl₃Si—CF₃ is supplied as the source, it is possible to form a film containing Si as the first element, F as a halogen, and Si—CF₃ as the above-described partial structure on the wafer 200. For example, when Cl₃Si—CCl₃ is supplied as the source, it is possible to form a film containing Si as the first element, Cl as a halogen, and Si—CCl₃ as the above-described partial structure on the wafer 200. In these cases, it is possible to sufficiently improve the ashing resistance of the film while sufficiently suppressing an increase in the k value of the film. In addition, the etching resistance of the film before and after ashing can be sufficiently improved.

(d) In at least one of the source supply step and the reactant supply step, by further supplying a catalyst to the wafer 200, the above-described effect can be obtained more remarkably. This is because, by supplying a catalyst, the above-described film forming reaction can be allowed to proceed under a low-temperature processing condition in which a source and a reactant are not thermally decomposed (gas-phase decomposition), that is, are not self-decomposed when the source and the reactant are present alone in the process chamber 201.

That is, in the source supply step, by supplying a source containing a chemical bond between the first element and carbon and a chemical bond between a halogen and carbon to the wafer 200 and further supplying a catalyst, the first layer can be formed under a condition that the chemical bond between the first element and carbon and the chemical bond between the halogen and carbon in the source are held without being broken. As a result, the first layer can contain more chemical bonds between the first element and carbon and more chemical bonds between the halogen and carbon.

In the reactant supply step, by supplying a reactant containing the second element different from the first element to the wafer 200 and further supplying a catalyst, the second layer can be formed under a condition that the chemical bond between the first element (contained in the first layer) and carbon and the chemical bond between the halogen and carbon in the source are held without being broken. As a result, the second layer can contain more chemical bonds between the first element and carbon and more chemical bonds between the halogen and carbon.

As described above, when the source containing a chemical bond between the first element and carbon and a chemical bond between a halogen and carbon is supplied to the wafer 200 in the source supply step, and a catalyst is further supplied to the wafer 200 in at least one of the source supply step and the reactant supply step, the film formed on the wafer 200 can contain more chemical bonds between the first element and carbon and more chemical bonds between the halogen and carbon.

In addition, when a catalyst is further supplied to the wafer 200 in at least one of the source supply step and the reactant supply step, by holding the above-described chemical bond contained in the first layer or the second layer without breaking the chemical bond, it is possible to suppress introduction of a chemical bond between carbon and hydrogen into the first layer or the second layer. As a result, the film formed on the wafer 200 can be a film having a small number of chemical bonds between carbon and hydrogen or a film not containing a chemical bond between carbon and hydrogen.

As a result, it is possible to further improve the ashing resistance of the film while suppressing an increase in the k value of the film. In addition, the etching resistance of the film before and after ashing can be further improved.

In addition, in the source supply step, by supplying a source including the above-described partial structure in which a halogen atom is bonded to each of at least two bonds among four bonds of a carbon atom and an atom of the first element is bonded to each of the remaining bonds to the wafer 200 and further supplying a catalyst, the first layer can be formed under a condition that the above-described partial structure is held without being broken. As a result, the first layer can include more partial structures described above.

In addition, in the reactant supply step, by supplying a reactant containing the second element different from the first element to the wafer 200 and further supplying a catalyst, the second layer can be formed under a condition that the above-described partial structure included in the first layer is held without being broken. As a result, the second layer can include more partial structure described above.

As described above, when the source including the partial structure described above is supplied to the wafer 200 in the source supply step, and a catalyst is further supplied to the wafer 200 in at least one of the source supply step and the reactant supply step, the film formed on the wafer 200 can include more partial structure described above.

In addition, when a catalyst is further supplied to the wafer 200 in at least one of the source supply step and the reactant supply step, by holding the above-described partial structure included in the first layer or the second layer without breaking the partial structure, it is possible to suppress introduction of a chemical bond between carbon and hydrogen into the first layer or the second layer. As a result, the film formed on the wafer 200 can be a film having a small number of chemical bonds between carbon and hydrogen or a film not containing a chemical bond between carbon and hydrogen.

As a result, it is possible to further improve the ashing resistance of the film while suppressing an increase in the k value of the film. In addition, the etching resistance of the film before and after ashing can be further improved.

(e) The above-described effect can be similarly obtained even in a case where a predetermined substance (a gaseous substance or a liquid substance) is arbitrarily selected from various sources, various reactants, various catalysts, and various inert gases described above to be used. Note that even when the halogen contained in the source is any one of Cl, F, Br, and I, the above-described effect can be obtained. In addition, when the halogen contained in the source is Cl or F, the above-described effect can be remarkably obtained.

### Other Embodiment of Present Disclosure

The embodiment of the present disclosure has been specifically described above. Note that, the present disclosure is not limited to the embodiment described above, and can be variously modified without departing from the gist thereof.

For example, the present disclosure can also be applied to a case where a film containing, as the first element, a semiconductor element such as silicon (Si) or germanium (Ge), or a metal element such as titanium (Ti), zirconium (Zr), hafnium (Hf), tantalum (Ta), aluminum (Al), molybdenum (Mo), tungsten (W), or ruthenium (Ru) is formed on a substrate. Processing procedures and processing conditions at the time of supplying the film forming agent can be similar to those in each step in the above-described embodiment. Even in these cases, effects similar to those in the above-described embodiment can be obtained.

In addition, for example, the present disclosure can also be applied to a case where a film containing, as the second element, an element such as oxygen (O), carbon (C), nitrogen (N), or boron (B) is formed on a substrate. For example, the present disclosure can also be applied to a case where a silicon oxycarbide film (SiOC film), a silicon oxycarbonitride film (SiOCN film), a silicon carbonitride film (SiCN film), a Si boron carbide film (SiBC film), a silicon boron carbonitride film (SiBCN film), or the like is formed on a substrate by the above-described processing sequence using, as a reactant, the above-described oxygen-containing gas, a carbon-containing gas such as an ethylene (C₂H₄) gas, an acetylene (C₂H₂) gas, or a propylene (C₃H₆) gas, a nitrogen-containing gas such as an ammonia (NH₃) gas or a diazene (N₂H₂) gas, a nitrogen and carbon-containing gas such as a triethylamine ((C₂H₅)₃N) gas or a trimethylamine ((CH₃)₃N,) gas, or a boron-containing gas such as a diborane (B₂H₆) gas or a trichloroborane (BCl₃) gas. Processing procedures and processing conditions at the time of supplying the film forming agent can be similar to those in each step in the above-described embodiment. Even in these cases, effects similar to those in the above-described embodiment can be obtained.

Preferably, a recipe used in each process is individually prepared according to processing contents and is recorded and stored in the memory 121c via an electric communication line or the external memory 123. Then, when each process is started, the CPU 121a preferably appropriately selects an appropriate recipe from among the plurality of recipes recorded and stored in the memory 121c according to the processing contents. As a result, it is possible to form films having various film types, composition ratios, film qualities, and film thicknesses with good reproducibility by using one substrate processing apparatus. In addition, it is possible to reduce a burden on an operator, and it is possible to quickly start each process while avoiding an operation error.

The recipe described above is not limited to a newly created recipe, but may be prepared by, for example, changing the existing recipe already installed in the substrate processing apparatus. In a case of changing the recipe, the changed recipe may be installed in the substrate processing apparatus via an electric communication line or a recording medium in which the recipe is recorded. The existing recipe already installed in the substrate processing apparatus may be directly changed by operating the input/output device 122 included in the existing substrate processing apparatus.

In the above-described embodiment, an example has been described in which a film is formed using a batch-type substrate processing apparatus that processes a plurality of substrates at a time. The present disclosure is not limited to the embodiment described above, and can be appropriately applied to a case of forming a film using a single wafer type substrate processing apparatus that processes one or more substrates at a time, for example. In the above-described embodiment, an example has been described in which a film is formed by using a substrate processing apparatus including a hot wall-type processing furnace. The present disclosure is not limited to the above-described embodiment, and can be suitably applied to a case of forming a film by using a substrate processing apparatus including a cold wall-type processing furnace.

Even in cases where such substrate processing apparatuses are used, each process can be performed according to processing procedures and processing conditions similar to those in the embodiment and modified examples described above, and effects similar to those in the embodiment and modified examples described above can be obtained.

The embodiment and modified examples described above can be used in combination as appropriate. Processing procedures and processing conditions at this time can be similar to, for example, the processing procedures and processing conditions in the embodiment and modified examples described above.

The present disclosure can improve film quality of a film formed on a substrate.

What is claimed is:

1. A method of processing a substrate, comprising:
forming a film containing a first element, a second element, carbon, and a halogen on the substrate by performing a cycle a predetermined number of times, the cycle including:
(a) supplying a source containing the first element, carbon, and the halogen and not containing a chemical bond between carbon and hydrogen to the substrate; and
(b) supplying a reactant containing the second element different from the first element to the substrate.

2. The method of processing a substrate according to claim 1, wherein the source contains a chemical bond between the first element and carbon and a chemical bond between the halogen and carbon.

3. The method of processing a substrate according to claim 2, wherein a molecule of the source includes a partial structure in which an atom of the halogen is bonded to each of at least two bonds among four bonds of a carbon atom, and an atom of the first element is bonded to each of the remaining bonds.

4. The method of processing a substrate according to claim 2, wherein a molecule of the source includes a partial structure in which an atom of the halogen is bonded to each of two bonds among four bonds of a carbon atom, and an atom of the first element is bonded to each of the remaining two bonds.

5. The method of processing a substrate according to claim 4, wherein the first element contains silicon (Si), the halogen contains fluorine (F), and the partial structure contains Si—CF₂—Si.

6. The method of processing a substrate according to claim 4, wherein the first element contains silicon (Si), the halogen contains chlorine (Cl), and the partial structure contains Si—CCl₂—Si.

7. The method of processing a substrate according to claim 2, wherein a molecule of the source includes a partial structure in which an atom of the halogen is bonded to each of three bonds among four bonds of a carbon atom, and an atom of the first element is bonded to the remaining one bond.

8. The method of processing a substrate according to claim 7, wherein the first element contains silicon (Si), the halogen contains fluorine (F), and the partial structure contains Si—CF₃.

9. The method of processing a substrate according to claim 7, wherein the first element contains silicon (Si), the halogen contains chlorine (Cl), and the partial structure contains Si—CCl₃.

10. The method of processing a substrate according to claim 1, wherein the second element contains oxygen.

11. The method of processing a substrate according to claim 1, wherein the reactant is an oxidant.

12. The method of processing a substrate according to claim 1, wherein a catalyst is further supplied to the substrate in at least one of (a) or (b).

13. The method of processing a substrate according to claim 2, wherein (a) and (b) are performed under a condition that a chemical bond between the first element and carbon and a chemical bond between the halogen and carbon in the source are held without being broken.

14. The method of processing a substrate according to claim 13, wherein the film contains the chemical bond between the first element and carbon and the chemical bond between the halogen and carbon.

15. The method of processing a substrate according to claim 3, wherein (a) and (b) are performed under a condition that the partial structure is held without being broken.

16. The method of processing a substrate according to claim 15, wherein the film includes the partial structure.

17. The method of processing a substrate according to claim 1, wherein the film does not contain a chemical bond between carbon and hydrogen.

18. A method of manufacturing a semiconductor device, comprising the method of processing a substrate according to claim 1.

19. A substrate processing apparatus comprising:
a source supply system configured to supply a source containing a first element, carbon, and a halogen and not containing a chemical bond between carbon and hydrogen to a substrate;
a reactant supply system configured to supply a reactant containing a second element different from the first element to the substrate; and
a controller configured to be capable of controlling the source supply system and the reactant supply system so as to form a film containing the first element, the second element, carbon, and the halogen on the substrate by performing a cycle a predetermined number of times, the cycle including: (a) supplying the source to the substrate; and (b) supplying the reactant to the substrate.

20. A non-transitory computer-readable recording medium storing a program that causes, by a computer, a substrate processing apparatus to perform a process comprising:
forming a film containing a first element, a second element, carbon, and a halogen on a substrate by performing a cycle a predetermined number of times, the cycle including:
(a) supplying a source containing the first element, carbon, and the halogen and not containing a chemical bond between carbon and hydrogen to the substrate; and
(b) supplying a reactant containing the second element different from the first element to the substrate.
